(19) United States
(12) Patent Application Publication
(10) Pub. No.: US 2024/0055493 A1
(43) Pub. Date: Feb. 15, 2024

(54) SEMICONDUCTOR DEVICE

(71) Applicant: Samsung Electronics Co., Ltd., Suwon-si (KR)

(72) Inventors: Sangcheol Na, Suwon-si (KR); Kyoungwoo Lee, Suwon-si (KR); Minchan Gwak, Suwon-si (KR); Gukhee Kim, Suwon-si (KR); Youngwoo Kim, Suwon-si (KR); Dongick Lee, Suwon-si (KR)

(21) Appl. No.: 18/364,521

(22) Filed: Aug. 3, 2023

(30) Foreign Application Priority Data
Aug. 11, 2022 (KR) 10-2022-0100802

(51) Int. Cl. H01L 29/417; H01L 23/48; H01L 29/786; H01L 29/775; H01L 29/06; H01L 29/423; H01L 29/49

(52) U.S. Cl. CPC H01L 29/41733; H01L 23/481; H01L 29/78696; H01L 29/775; H01L 29/0673; H01L 29/42392; H01L 29/495

(57) ABSTRACT

A semiconductor device includes a substrate having a fin-type active pattern, source/drain regions on the fin-type active pattern, an interlayer insulating layer on the isolation insulating layer, and on the source/drain region, a contact structure electrically connected to the source/drain regions, a buried conductive structure electrically connected to the contact structure and buried in the interlayer insulating layer, and a power delivery structure that penetrates the substrate, and is in contact with a bottom surface of the buried conductive structure. The buried conductive structure includes a first contact plug, and a first conductive barrier on a side surface of the first contact plug and spaced apart from a bottom surface of the first contact plug. The power delivery structure includes a second contact plug in direct contact with the bottom surface of the first contact plug.

### CROSS TO REFERENCE TO RELATED APPLICATION(S)

This application claims benefit of priority to Korean Patent Application No. 10-2022-0100802 filed on Aug. 11, 2022 in the Korean Intellectual Property Office, the disclosure of which is incorporated herein by reference in its entirety.

### BACKGROUND

Example embodiments of the present disclosure relate to a semiconductor device.

In various semiconductor devices, such as a logic circuit and a memory, an active region such as a source and a drain may be connected to a metal wiring of a back end of line (BEOL) through a contact structure.

To connect at least a portion of the BEOL (e.g., a power line) to an element disposed on the backside of a substrate, a method of forming a conductive through structure such as a TSV from the backside of the semiconductor substrate has been necessary.

### SUMMARY

Example embodiments of the present disclosure is to provide a semiconductor device which may improve contact resistance of a buried conductive structure and a power delivery structure.

According to example embodiments of the present disclosure, a semiconductor device includes a substrate having first and second surfaces opposing each other, and having a fin-type active pattern that extends in a first direction, an isolation insulating layer on side surfaces of the fin-type active pattern, a gate structure that extends in a second direction and intersects the fin-type active pattern, source/drain regions on the fin-type active pattern and on side surfaces of the gate structure, an interlayer insulating layer on the isolation insulating layer, on side surfaces of the gate structure and covering the source/drain region, a contact structure that penetrates the interlayer insulating layer and is electrically connected to the source/drain regions, a buried conductive structure electrically connected to the contact structure and in the interlayer insulating layer and the isolation insulating layer, and a power delivery structure that extends from the second surface of the substrate toward the first surface of the substrate, in contact with a bottom surface of the buried conductive structure, and is electrically connected to the buried conductive structure. The buried conductive structure includes a first contact plug, a first conductive barrier on a side surface of the first contact plug and spaced apart from a bottom portion of the side surface of the first contact plug, and a first insulating liner on the first conductive barrier. The power delivery structure includes a second contact plug, a second conductive barrier on a side surface of the second contact plug and an upper surface of the second contact plug and in direct contact with the bottom surface of the first contact plug, and a second insulating liner between the second conductive barrier and the substrate.

According to example embodiments of the present disclosure, a semiconductor device includes a substrate having first and second surfaces opposing each other, that extends in a first direction, and having a fin-type active pattern defined by an isolation insulating layer, a source/drain region on the fin-type active pattern, an interlayer insulating layer on the isolation insulating layer and on the source/drain regions, a contact structure that penetrates the interlayer insulating layer and is electrically connected to the source/drain regions, a first wiring portion on the interlayer insulating layer and electrically connected to the contact structure, a buried conductive structure in the interlayer insulating layer and the isolation insulating layer, electrically connected to the contact structure, and having a bottom surface that penetrates the substrate and spaced apart from a second surface of the substrate, and a second wiring portion on the second surface of the substrate and having a power delivery structure electrically connected to a bottom surface of the buried conductive structure. The buried conductive structure includes a first contact plug, a first conductive barrier on a side surface of the first contact plug, and a first insulating liner on the first conductive barrier, The power delivery structure includes a second contact plug, and a second conductive barrier on a side surface and an upper surface of the second contact plug and in direct contact with the bottom surface of the first contact plug.

According to example embodiments of the present disclosure, a semiconductor device includes a substrate having a first surface and a second surface opposing each other, and having an active region defined by a first isolation insulating layer, a fin-type active pattern that extends in a first direction on the active region and defined by a second isolation insulating layer having a depth less than a depth of the first isolation insulating layer with respect to the substrate, a source/drain region on the fin-type active pattern, a plurality of channel layers stacked and spaced apart from each other on the fin-type active pattern, a gate electrode intersecting the fin-type active pattern, that extends in a second direction intersecting the first direction, and on the plurality of channel layers, a gate insulating layer between the plurality of channel layers and the gate electrode, an interlayer insulating layer on the second isolation insulating layer and on the gate electrode and the source/drain regions, a contact structure that penetrates the interlayer insulating layer and is electrically connected to the source/drain regions, a buried conductive structure electrically connected to the contact structure, buried in the first isolation insulating layer and the second isolation insulating layer, and that extends into the substrate, and a power delivery structure that extends into the substrate from the second surface of the substrate and is electrically connected to a bottom surface of the buried conductive structure, The buried conductive structure includes a first contact plug, a first conductive barrier on a side surface of the first contact plug, and a first insulating liner on the first conductive barrier. The power delivery structure includes a second contact plug, a second conductive barrier on a side surface and an upper surface of the second contact plug and in direct contact with the bottom surface of the first contact plug, and a second insulating liner between the second conductive barrier and the substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan diagram illustrating a semiconductor device according to example embodiments of the present disclosure;

FIG. 2 is cross-sectional diagrams illustrating the semiconductor device illustrated in FIG. 1 taken along lines I-I′ and II-II′.

FIG. 3 is an enlarged cross-sectional diagram illustrating region “A1” of the semiconductor device illustrated in FIG. 2;

FIG. 4 is cross-sectional diagrams illustrating a semiconductor device according to example embodiments of the present disclosure;

FIG. 5 is enlarged cross-sectional diagrams illustrating region “A2” of the semiconductor device illustrated in FIG. 4;

FIG. 6 is cross-sectional diagrams illustrating a semiconductor device according to example embodiments of the present disclosure;

FIG. 7 is enlarged cross-sectional diagrams illustrating region “A3” of the semiconductor device illustrated in FIG. 6;

FIG. 8 is a plan diagram illustrating a semiconductor device according to example embodiments of the present disclosure;

FIG. 9 is cross-sectional diagrams illustrating the semiconductor device illustrated in FIG. 8 taken along lines I-I′ and II-II′.

FIG. 10 is an enlarged cross-sectional diagram illustrating region “A4” of the semiconductor device illustrated in FIG. 9; and

FIGS. 11A to 11F are cross-sectional diagrams illustrating processes of a method of manufacturing the semiconductor device illustrated in FIG. 2.

### DETAILED DESCRIPTION

Hereinafter, embodiments of the present disclosure will be described as follows with reference to the accompanying drawings.

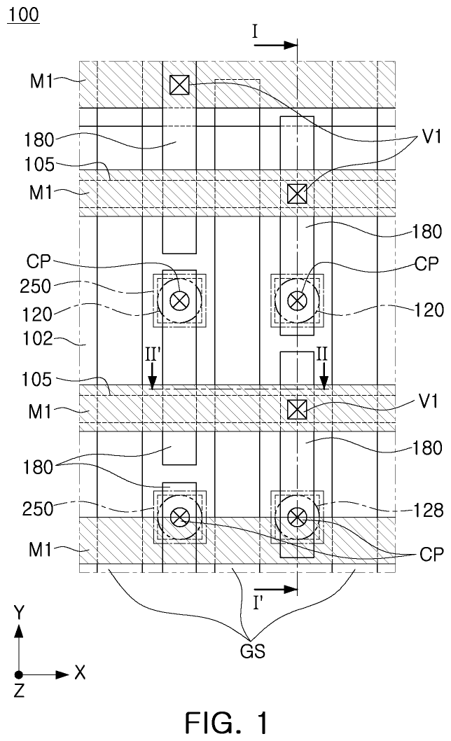

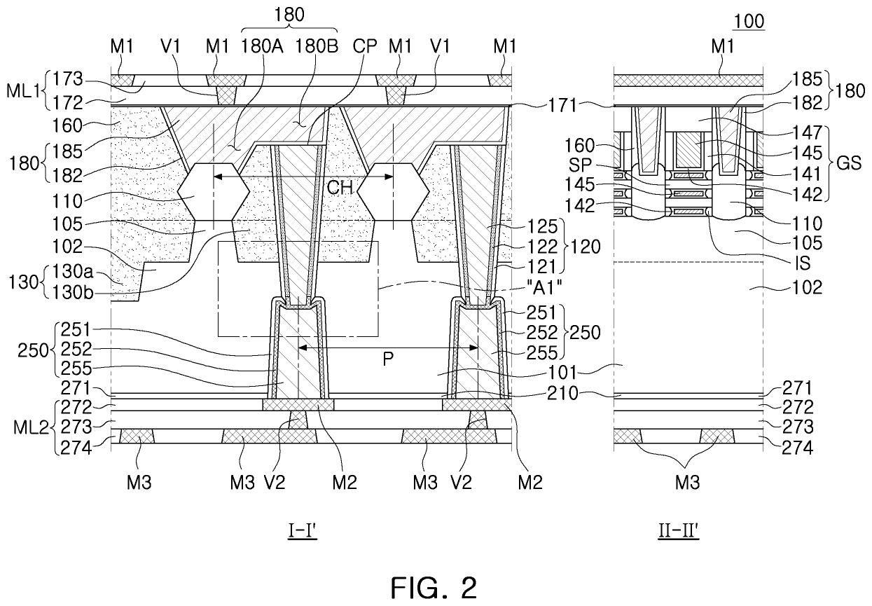

FIG. 1 is a plan diagram illustrating a semiconductor device according to example embodiments. FIG. 2 is cross-sectional diagrams illustrating the semiconductor device illustrated in FIG. 1 taken along lines I-I′ and II-II′.

Referring to FIGS. 1 and 2, the semiconductor device 100 according to the example embodiments may include a substrate 101 having a first surface on which an active region 102 is formed and a second surface opposing the first surface, a fin-type active pattern 105 extending in a first direction (e.g., X-direction) on the upper surface of the active region 102, a gate structure GS extending in a second direction (e.g., Y-direction) intersecting the first direction (e.g., X-direction) and crossing the fin-type active pattern 105, and a source/drain regions 110 disposed on the fin-type active pattern 105 on both sides of the gate structure GS.

The semiconductor device 100 according to example embodiments may include a buried conductive structure 120 electrically connected to the source/drain region 110, and a power delivery structure 250 connected to the buried conductive structure 120 through the substrate 101. The power delivery structure 250 may be configured to receive power from the second wiring portion ML2 disposed on the rear surface, that is, the second surface of the substrate 101 and may transmit the power to a device region (e.g., the source/drain region 110). The second wiring portion ML2 may include a plurality of second dielectric layers 272, 273, and 274, metal wirings M2 and M3, and a metal via V2. A power delivery network employed in the example embodiments will be described later.

The substrate 101 may include, for example, a semiconductor such as Si or Ge, or a compound semiconductor such as SiGe, SiC, GaAs, InAs or InP. In some example embodiments, the substrate 101 may have a silicon on insulator (SOI) structure. The active region 102 may be a conductive region such as a well doped with an impurity or a structure doped with an impurity. In some example embodiments, although not limited thereto, the active region 102 may be an N-type well for a P-MOS transistor or a P-type well for an N-MOS transistor.

The isolation insulating layer 130 may be provided to define the active region 102 including the fin-type active pattern 105. A portion of the fin-type active pattern 105 may protrude from a surface of the isolation insulating layer 130. For example, the isolation insulating layer 130 may include silicon oxide or a silicon oxide-based insulating material. The isolation insulating layer 130 may include a first isolation insulating layer 130a defining the active region 102 excluding the fin-type active pattern 105 and a second isolation insulating layer 130b defining the fin-type active pattern 105. The first isolation insulating layer 130a may have a bottom surface having a depth greater than that of the second isolation insulating layer 130b with respect to the substrate. For example, the first isolation insulating layer 130a may be referred to as deep trench isolation (DTI), and the second isolation insulating layer 130b may be referred to as shallow trench isolation (STI).

Referring to FIG. 1, the fin-type active pattern 105 may extend in the first direction (e.g., the X-direction) on the upper surface of the active region 102. The fin-type active pattern 105 may have a structure protruding upwardly (e.g., in the Z-direction) from the upper surface of the active region 102. A plurality of semiconductor patterns SP may be disposed to be spaced apart from each other in a third direction (e.g., Z-direction) perpendicular to the upper surface of the substrate 101 on the fin-type active pattern 105. The fin-type active pattern 105 and the plurality of semiconductor patterns SP, also referred to as channel layers, may be provided as a multi-channel layer of a transistor. In example embodiments, the number of the plurality of semiconductor patterns SP may be three, but the number of the plurality of semiconductor patterns SP is not limited to any particular example. For example, the semiconductor patterns SP may include at least one of silicon (Si), silicon germanium (SiGe), and germanium (Ge).

As illustrated in FIG. 1, the semiconductor device 100 according to the example embodiments may include a line-shaped gate structure GS extending in the second direction (e.g., the Y-direction). The gate structure GS may be disposed in one region of the fin-type active pattern 105.

As illustrated in FIG. 2, the gate structure GS employed in the example embodiments may include gate spacers 141, a gate insulating layer 142 and a gate electrode 145 disposed in sequence between the gate spacers 141, and a gate capping layer 147 disposed on the gate electrode 145. For example, the gate spacers 141 may include an insulating material such as SiOCN, SiON, SiCN, or SiN. The gate insulating layer 142 may be formed of, for example, a silicon oxide layer, a high-K layer, or a combination thereof. The high-K layer may include a material having a dielectric constant (e.g., about 10 to 25) that is higher than that of a silicon oxide layer. For example, the high-K film may include a material selected from hafnium oxide, hafnium oxynitride, hafnium silicon oxide, lanthanum oxide, lanthanum aluminum oxide, and/or combinations thereof, but example embodiments thereof is not limited thereto. The gate electrode 145 may include a conductive material, such as, for example, a metal nitride such as titanium nitride (TiN), tantalum nitride (TaN), or tungsten nitride (WN), and/or a metal material such as aluminum (A1), tungsten (W) or molybdenum (Mo) and/or a semiconductor material such as doped polysilicon. In example embodiments, the gate electrode 145 may be configured as multiple layers including two or more films. Also, the gate capping layer 147 may include, for example, silicon nitride, silicon oxynitride, silicon carbonitride, and/or silicon oxycarbonitride.

The source/drain region 110 may be disposed on the region of the fin-type active pattern 105 disposed on both sides of the gate structure GS. The source/drain regions 110 may be connected to both ends of the plurality of semiconductor patterns SP in the first direction (e.g., the X-direction), respectively. The gate electrode 145 may extend in the second direction (e.g., the Y-direction) to intersect the fin-type active pattern 105 while surrounding the plurality of semiconductor patterns SP. The gate electrode 145 may be disposed in spaces between the gate spacers 141 and may also be interposed between the plurality of semiconductor patterns SP.

Internal spacers IS provided between each of the source/drain regions 110 and the gate electrode 145 may be included. The internal spacers IS may be on both sides of the gate electrode 145 interposed between the plurality of semiconductor patterns SP in the first direction (e.g., the X-direction). The plurality of semiconductor patterns SP may be connected to the source/drain regions 110 on both sides thereof, respectively, and the gate electrode 145 interposed between the plurality of semiconductor patterns SP may be electrically insulated from the source/drain regions 110 on both sides thereof by the internal spacers IS. The gate insulating layer 142 may be interposed between each of the gate electrode 145 and the semiconductor pattern SP, and may also extend to a region between the gate electrode 145 and the internal spacers IS. As described above, the semiconductor device 100 according to the example embodiments may be included in a gate-all-around type field effect transistor.

The source/drain region 110 may include a selective epitaxial growth (SEG) epitaxial pattern using the recessed surface (including side surfaces of the plurality of semiconductor patterns SP) of the fin-type active pattern 105 on both sides of the gate structure GS as a seed. The source/drain region 110 may also be referred to as a raised source/drain (RSD). For example, the source/drain regions 110 may be formed of Si, SiGe, or Ge, and may have N-type conductivity or P-type conductivity. When the P-type source/drain region 110 is formed, the source/drain region 110 may be regrown with SiGe, and as the P-type impurity, for example, boron (B), indium (In), gallium (Ga), boron trifluoride (BF3), or the like, may be doped. When the N-type source/drain region 110 is formed of silicon (Si), as the N-type impurities, for example, phosphorus (P), nitrogen (N), arsenic (As), antimony (Sb), and the like may be doped. The source/drain region 110 may have a different shape along a crystallographically stable surface during the growth process. For example, as illustrated in FIG. 2, the source/drain region 110 may have a pentagonal cross-section (in the case of P-type conductivity), or alternatively, the source/drain region 110 may have a hexagonal or polygonal cross-section having gentle angles (in the case of N-type conductivity).

The semiconductor device 100 according to the example embodiments may include an interlayer insulating layer 160 disposed on the isolation insulating layer 130. The interlayer insulating layer 160 may partially cover or overlap the source/drain region 110 and may be disposed around the gate structure GS. For example, the interlayer insulating layer 160 may include flowable oxide (FOX), tonen silazen (TOSZ), undoped silica glass (USG), borosilica glass (BSG), phosphosilaca glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or a combination thereof. The interlayer insulating layer 161 may be formed using a chemical vapor deposition (CVD) process, a flowable-CVD process, or a spin coating process.

The contact structure 180 may penetrate through the interlayer insulating layer 160 and may be connected to the source/drain region 110. The contact structure 180 may interconnect the source/drain region 110 and the first wiring portion ML1. The first wiring portion ML1 may include a plurality of first dielectric layers 172 and 173, the metal wiring M1, and the metal via V1. The contact structure 180 may include a conductive barrier 182 and a contact plug 185.

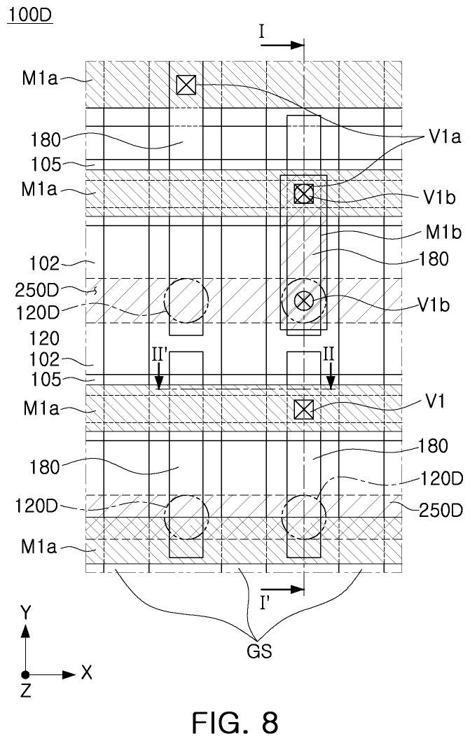

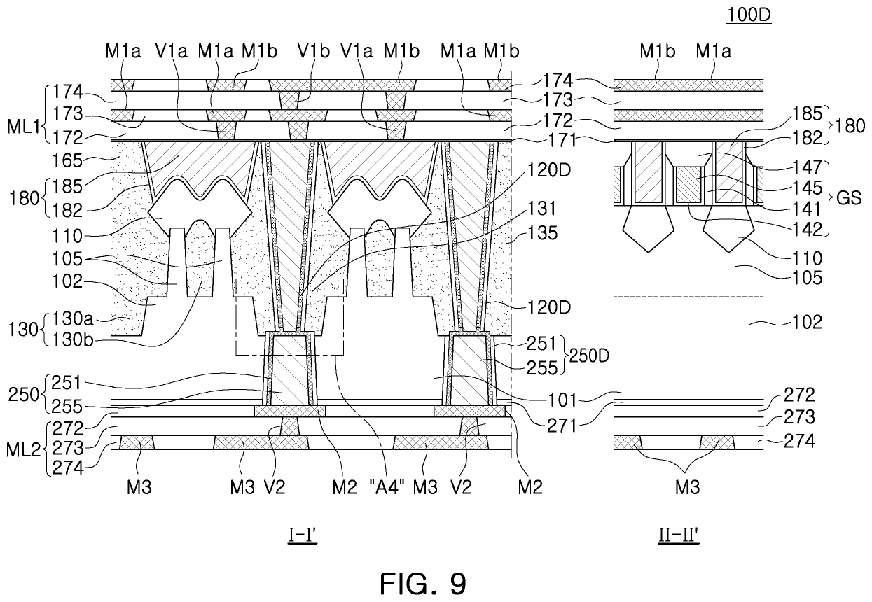

The buried conductive structure 120 may be buried in the interlayer insulating layer 160 and the isolation insulating layer 130 to be electrically connected to the source/drain region 110. The contact structure 180 may be configured to connect the source/drain region 110 to the buried conductive structure 120. Specifically, the contact structure 180 employed in example embodiments may include a first contact portion 180A connected to the source/drain region 110 and a second contact portion 180B connected to the buried conductive structure 120. The second contact portion 180B may extend in a second direction (e.g., a Y-direction) from the first contact portion 180A and may be easily connected to the buried conductive structure 120. FIG. 1 illustrates an example of an arrangement of the second contact portion 180B and the contact points CP of the buried conductive structure 120. In example embodiments, the buried conductive structure 120 may be connected to the contact structure 180 through the first wiring portion ML1 instead of being directly connected to the contact structure 180 (see FIGS. 8 and 9).

The buried conductive structure 120 may be buried in the interlayer insulating layer 160 and the second isolation insulating layer 130b, may extend into the substrate 101 and may be connected to the power delivery structure 250. The power delivery structure 250 may extend from the second surface of the substrate 101 toward the first surface of the substrate 101 and may be connected to the buried conductive structure 120. The power delivery structure 250 may be in contact with the bottom surface of the buried conductive structure 120 in the substrate 101. In example embodiments, each of the buried conductive structure 120 and the power delivery structure 250 may include a via structure such as a pillar shape (see FIG. 1). However, example embodiments thereof is not limited thereto, and in example embodiments, the power delivery structure 250C may have a rail shape extending in the first direction (e.g., the X-direction) (see FIG. 8).

In example embodiments, when the cell height (CH) is defined as a pitch of the adjacent fin-type active pattern 105 in the second direction (e.g., the Y-direction), the power delivery structure 250 may be defined as 0.5 to 1 times the cell height.

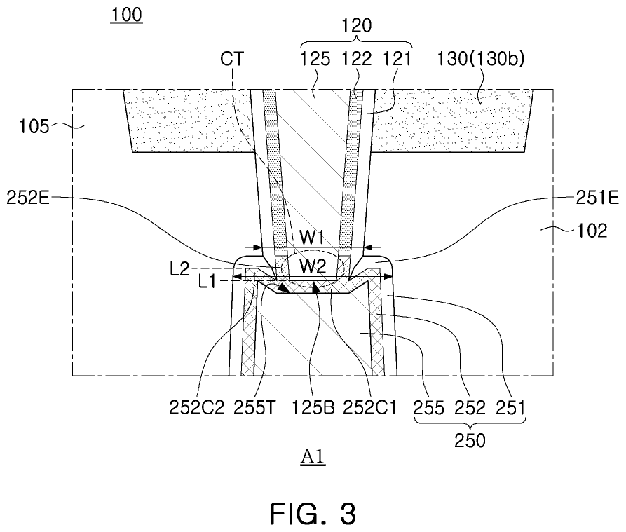

FIG. 3 is an enlarged cross-sectional diagram illustrating region “A1” of the semiconductor device illustrated in FIG. 2.

Referring to FIG. 3 along with FIG. 2, the buried conductive structure 120 may extend into the second isolation region 130b and into the active region 102 of the substrate 101. The buried conductive structure 120 may include a portion buried in the interlayer insulating layer 160 and the second isolation insulating layer 130b and a portion buried in the active region 102. The buried conductive structure 120 may include a first contact plug 125, a first conductive barrier 122 surrounding a side surface of the first contact plug 125, and a first insulating liner 121 disposed on the first contact plug 125.

The power delivery structure 250 may extend from the second surface of the substrate 101 into the substrate 101, and may include a second contact plug 255, a second conductive barrier 252 disposed on the side surface and an upper surface 255T of the second contact plug 255, and a second insulating liner 251 disposed between the second conductive barrier 252 and the substrate 101.

In example embodiments, the first conductive barrier 122 may be disposed on a side surface of the first contact plug 125 and be open to the bottom surface 125B of the first contact plug 125. The second conductive barrier 252 may extend on the upper surface 255T of the second contact plug 255 to be in direct contact with the open part of bottom surface 125B of the first contact plug 125.

As such, only the second conductive barrier 252 may be present without the first conductive barrier 122 on the interfacial surface between the first contact plug 125 and the second contact plug 255. By partially removing the second conductive barrier 252 having relatively high electrical resistance, contact resistance between the buried conductive structure 120 and the power delivery structure 250 may be significantly reduced (e.g., up to 40%).

In example embodiments, the first conductive barrier 122 may be partially removed from the side region adjacent to the bottom surface 125T of the first contact plug 125 such that the side region may be open. The second conductive barrier 252 may have a portion 252E extending along the adjacent side region of the first contact plug 125.

Since the contact region CT of the buried conductive structure 120 and the power delivery structure 250 may be increased by the area of the extended portion 252E of the second conductive barrier 252 as above, contact resistance may be further reduced. In example embodiments, the extended portion 252E of the second conductive barrier 252 may be disposed between the side surface of the first contact plug 125 and the first insulating liner 121.

The second conductive barrier 252 may include a first region 252C1 in contact with the bottom surface 125B of the first contact plug 125 and a second region 252C2 disposed around the first region 252C1, the second region 252C2 may be recessed toward the bottom surface 125B (or the first surface of the substrate 101) of the first contact plug 125 rather than the first region 252C1. The level L2 of the second region 252C2 may be more adjacent to the bottom surface 125B of the first contact plug 125 than the level L1 of the first region 252C1.

Similarly, the upper surface of the power delivery structure 250 may have a first region in contact with the bottom surface of the buried conductive structure 120, and a second region disposed around the first region, and the second region may be recessed toward the first surface of the substrate 101 rather than the first region.

In example embodiments, the second conductive barrier 252 may have a portion 252E extending to a second region of the upper surface of the power delivery structure 250. The extended portion 252E of the second conductive barrier 252 may electrically insulate the power delivery structure 250 from the substrate 101.

For example, at least one of the first conductive barrier 122 and the second conductive barrier 252 may include Ta, TaN, Mn, MnN, WN, Ti, TiN, or a combination thereof. In example embodiments, the first conductive barrier 122 and the second conductive barrier 252 may include different conductive materials. In example embodiments, the first conductive barrier 122 may include TiN. The second conductive barrier 252 may include TaN or Co/TaN.

For example, at least one of the first contact plug 125 and the second contact plug 255 may include Cu, Co, Mo, Ru, W, or an alloy thereof. In example embodiments, the first contact plug 125 and the second contact plug 255 may include different conductive materials. In example embodiments, the first contact plug 125 may include Mo. The second conductive barrier 252 may include Cu or W.

For example, at least one of the first insulating liner 121 and the second insulating liner 251 may include, for example, SiO₂, SiN, SiCN, SiC, SiCOH, SiON, Al₂O₃, AlN, or a combination thereof.

The width W1 of the bottom surface of the buried conductive structure 120 may be in the range of 0.3 to 1.2 times the width W2 of the upper surface of the power delivery structure 250. In example embodiments, the upper surface of the power delivery structure 250 may have a width W2 greater than the width W1 of the bottom surface of the buried conductive structure 120.

As illustrated in FIG. 2, the contact structure 180 may be connected to a first wiring portion ML1 included in a back end of lines (BEOL). The first wiring portion ML1 may be configured to connect a plurality of devices (e.g., the source/drain region 110 and the gate electrode 145) implemented on the first surface of the substrate 101, in particular, the active region 102, to each other.

The first wiring portion ML1 may include a plurality of first dielectric layers 172 and 173, the metal wiring M1, and the metal via V1. The plurality of first dielectric layers 172 and 173 may include first lower dielectric layers 172 and 173 disposed on the interlayer insulating layer 160. A metal wiring M1 may be formed on the first upper dielectric layer 173, and a metal via V1 may be formed on the first lower dielectric layer 172. Here, each of the metal vias V1 may be connected to the contact structure 180 through the metal wiring M1 (see FIGS. 1 and 2).

For example, the first dielectric layers 172 and 173 may include silicon oxide, silicon oxynitride, SiOC, SiCOH, or a combination thereof. For example, the metal wiring M1 and the metal via V1 may include copper or a copper-containing alloy. In example embodiments, the metal wiring M1 and the metal via V1 may be formed together using a dual-damascene process.

According to some embodiments, an etch stop layer 171 disposed between the interlayer insulating layer 160 and the first dielectric layers 172 and 173 may be further included. The etch stop layer 171 may serve as an etch stopper, and may also prevent a metal (e.g., Cu) included in the metal wiring M1 and the metal via V1 from diffusing into the lower region. For example, the etch stop layer 171 may include aluminum nitride (AlN), but example embodiments thereof are not limited thereto.

In example embodiments, the second wiring portion ML2 connected to the power delivery structure 250 may be disposed on the second surface of the substrate 101. The second wiring portion ML2 employed in the example embodiments may be understood as a wiring portion replacing a portion of the first wiring portion ML1 which is a BEOL. In the example embodiments, the second wiring portion ML2 may be a wiring portion for power transmission, and the first wiring portion ML1 may be provided as a signal transmission wiring portion. A back insulating layer 210 may be disposed on the second surface of the substrate 101, and a second wiring portion ML2 connected to the power delivery structure 250 may be disposed on the back insulating layer. The second wiring portion ML2 may include a plurality of second dielectric layers 272, 273, and 274, metal wirings M2 and M3, and a metal via V2, similarly to the first wiring portion ML1.

As described above, in the example embodiments, the signal network may be connected to the device region (e.g., the source/drain region 110 and the gate electrode 145) from the first wiring portion ML1 disposed on the first surface of the substrate 101 through the contact structure 180, and the power transmission network may penetrate the substrate 101 from the second wiring portion ML2 disposed on the second surface of the substrate 101 and may be connected to the device region (e.g., the source/drain region 110).

The power delivery network employed in the example embodiments may include a buried conductive structure 120 and a power delivery structure 250 connected thereto, and by removing the portion of the first conductive barrier 122 which is a resistive element from the contact interfacial surface between the buried conductive structure 120 and the power delivery structure 250, only the second conductive barrier 252 may be provided, such that contact resistance may improve. Also, by exposing one region of the side surface of the second contact plug 255 adjacent to the bottom surface 255B, the contact region may be increased, thereby greatly improving contact resistance.

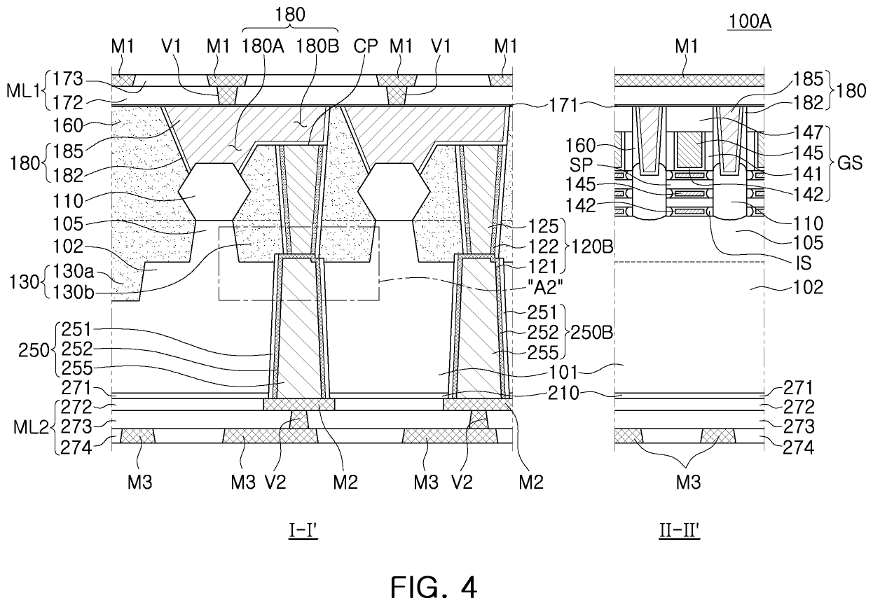

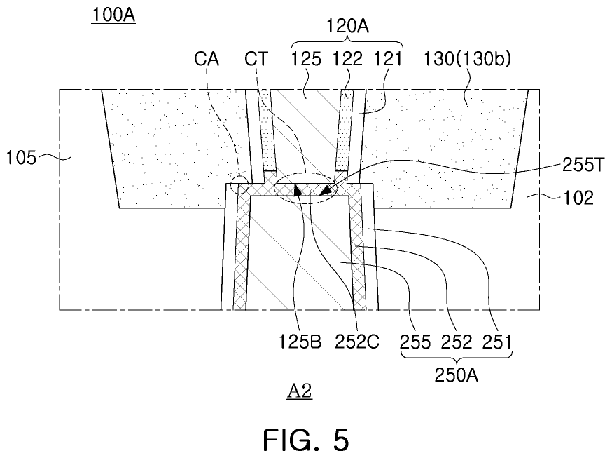

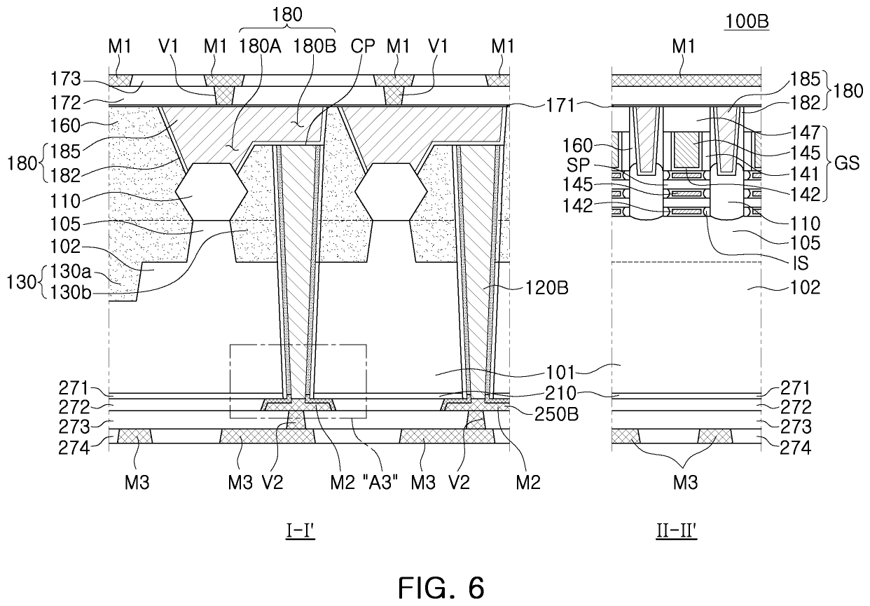

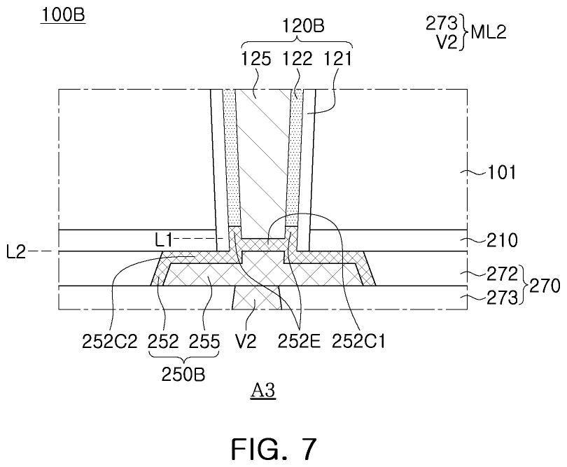

The power delivery network may be varied in example embodiments. In the aforementioned example embodiments, the contact region CT of the buried conductive structure 120 and the power delivery structure 250 may be disposed in the substrate, but example embodiments thereof is not limited thereto. In example embodiments, the contact region CT of the buried conductive structure 120A and the power delivery structure 250A may be disposed in the region of the isolation insulating layer 130 adjacent to the first surface of the substrate 101 (FIG. 4 and FIG. 5). In example embodiments, the contact region CT of the buried conductive structure 120 and the power delivery structure 250 may be disposed on an interfacial surface between the second surface of the substrate 101 and the second wiring portion ML2 (see FIGS. 6 and 7).

FIG. 4 is cross-sectional diagrams illustrating a semiconductor device according to example embodiments. FIG. 5 is enlarged cross-sectional diagrams illustrating region “A2” of the semiconductor device illustrated in FIG. 4.

Referring to FIGS. 4 and 5, the semiconductor device 100A according to example embodiments may be configured similarly to the semiconductor device 100 illustrated in FIGS. 1 to 3 other than the configuration in which the buried conductive structure 120 may extend from the second isolation insulating layer 130b to the first surface of the substrate 101. Also, the components in the example embodiments may be understood by referring to the descriptions of the same or similar components of the semiconductor device 100 illustrated in FIGS. 1 to 3, unless otherwise indicated.

In the example embodiments, the buried conductive structure 120A may be connected to the power delivery structure 250A in the region of the isolation insulating layer 130 adjacent to the first surface of the substrate 101. Specifically, the buried conductive structure 120A may extend to the first surface of the substrate 101 through the isolation insulating layer 130. The power delivery structure 250A may extend from the second surface of the substrate 101, may penetrate through the substrate 101, and may be connected to the buried conductive structure 120A.

The power delivery structure 250A may be in contact with the buried conductive structure 120A in a region adjacent to the first surface of the substrate 101 of the isolation insulating layer 130 as described above.

Referring to FIG. 5, since only the second conductive barrier 252 is disposed without the first conductive barrier 122 in the contact region CT of the first contact plug 125 and the second contact plug 255, contact resistance between the buried conductive structure 120A and the power delivery structure 250A may improve. Also, by exposing a region adjacent to the bottom surface 255B among the side surfaces of the second contact plug 255 and extending the second conductive barrier 252 along the side region, the contact area may be increased such that contact resistance may significantly improve.

In the example embodiments, the upper surface of the power delivery structure 250 may have a first region in contact with the bottom surface of the buried conductive structure 120, and a second region disposed around the first region. The second region of the upper surface of the power delivery structure 250 may be provided by the second conductive barrier 252 and may be in contact with the isolation insulating layer 130.

FIG. 6 is cross-sectional diagrams illustrating a semiconductor device according to example embodiments. FIG. 7 is enlarged cross-sectional diagrams illustrating region “A3” of the semiconductor device illustrated in FIG. 6.

Referring to FIGS. 6 and 7, the semiconductor device 100B according to the example embodiments may be configured similarly to the semiconductor device 100 illustrated in FIGS. 1 to 3, other than the configuration in which the buried conductive structure 120 may penetrate the substrate 101 and may have a bottom surface open from the second surface of the substrate 101. Also, the components in the example embodiments may be understood by referring to the descriptions of the same or similar components of the semiconductor device 100 illustrated in FIGS. 1 to 3, unless otherwise indicated.

The buried conductive structure 120B may be buried in the interlayer insulating layer 160 and the isolation insulating layer 130, and may penetrate the substrate 101. The buried conductive structure 120B may have a bottom surface open from the second surface of the substrate 101. The power delivery structure 250B employed in the example embodiments may be disposed on the second wiring portion ML2, which includes a dielectric layer 273 and via V2. The power delivery structure 250B may be configured and may be connected to an open bottom surface of the buried conductive structure 120B, as illustrated in FIG. 7. The power delivery structure 250B may be connected to another wiring (e.g., a power supply line) of the second wiring portion ML2 through the metal via V2.

Similarly to the aforementioned example embodiments, only the second conductive barrier 252 may be disposed without the first conductive barrier 122 in the contact region CT of the first contact plug 125 and the second contact plug 255.

In the buried conductive structure 120B, the first conductive barrier 122 may be disposed on the side surface of the first contact plug 125 to open a side region adjacent to the bottom surface 125B of the first contact plug 125, and the second conductive barrier 252 may have a portion 252E extending along the adjacent side region of the first contact plug 125. A contact area between the buried conductive structure 120 and the power delivery structure 250 may be increased by the extended portion 252E of the second conductive barrier 252, thereby improving contact resistance.

Also, the second conductive barrier 252 may have a first region 252C1 in contact with the bottom surface 125B of the first contact plug 125 and a second region 252C2 disposed around the first region 252C1, and the first region 252C1 may be recessed toward a first surface of the substrate 101, that is, a bottom surface 125B of the first contact plug 125, rather than the second region 252C2. That is, the level L1 of the first region 252C1 may be more adjacent to the bottom surface 125B of the first contact plug 125 than the level L2 of the second region 252C2.

FIG. 8 is a plan diagram illustrating a semiconductor device according to example embodiments. FIG. 9 is cross-sectional diagrams illustrating the semiconductor device illustrated in FIG. 8 taken along lines I-I′ and II-II′.

Referring to FIGS. 8 and 9, the semiconductor device 100C according to the example embodiments may be configured similarly to the semiconductor device 100 illustrated in FIGS. 1 to 3B, other than the configuration in which the channel region may be provided as the active fin 105, the configuration in which the buried conductive structure 120D may be connected to the contact structure 180 through the first wiring portion ML1, the configuration in which the buried conductive structure 120D may be connected to the power delivery structure 250D in the region adjacent to the first surface of the substrate 101 through the first and second isolation insulating layers 130a and 130b, and the configuration in which the power delivery structure 250D may have a rail structure. Also, the components in the example embodiments may be understood by referring to the descriptions of the same or similar components of the semiconductor device 100 illustrated in FIGS. 1 to 3B, unless otherwise indicated.

Differently from the aforementioned example embodiments, the channel region employed in the example embodiments may include active fins 105 provided in a three-dimensional channel structure. Each of the active fins 105 may have a structure protruding upward (e.g., in the Z-direction) from the upper surface of the substrate 101 (in particular, the active region 102), and may extend in a first direction (e.g., in the X-direction). As illustrated in FIGS. 8 and 9, the active fins 105 may be arranged side by side in the second direction (e.g., Y-direction) in the active region 102. In the example embodiments, two active fins 105? arranged adjacently to each other may provide a channel region for a transistor. In the example embodiments, the two active fins 105 may be provided, but example embodiments thereof is not limited thereto, and a single active fin 105 or more than two active fins 105 may be provided (e.g., three active fins 105).

The semiconductor device 100C according to example embodiments may include a source/drain region 110 formed throughout two active fins 105 and a contact structure 180 connected to the source/drain region 110.

The gate structure GS employed in example embodiments may overlap one region of each of the active fins 105. The gate structure GS may include gate spacers 141, a gate insulating layer 142 and a gate electrode 145 disposed in sequence between the gate spacers 141, and a gate capping layer 147 disposed on the gate electrode 145.

In the example embodiments, the buried conductive structure 120 may be electrically connected to the contact structure 180 through the first wiring portion ML1. The first wiring portion ML1 may be connected to the upper surface of the contact structure 180 through one metal via V1 and may be connected to the buried conductive structure 120D through another metal via V1.

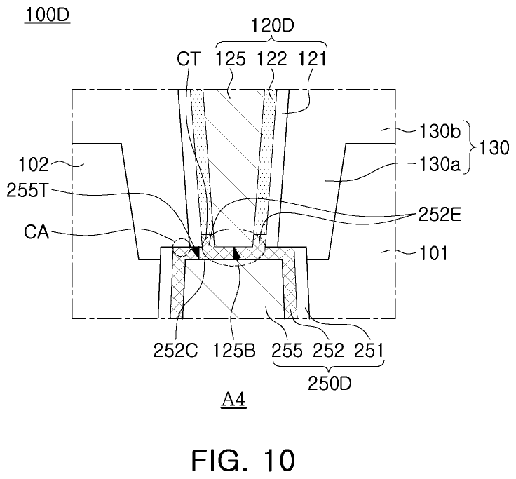

As illustrated in FIGS. 9 and 10, the buried conductive structure 120D may be formed in a region in which the first isolation insulating layer 130a is disposed. The buried conductive structure 120D may be formed throughout the second isolation insulating layer 130b and also throughout the first isolation insulating layer 130a, and the bottom surface of the buried conductive structure 120D may be disposed in the region adjacent to the first surface of the substrate 101. The power delivery structure 250D may penetrate through the substrate 101 from the second surface of the substrate 101. The power delivery structure 250D may be connected to the buried conductive structure 120D in a region adjacent to the first surface of the substrate 101.

As illustrated in FIG. 8, the power delivery structure 250D employed in example embodiments may have a rail structure extending in the first direction. Even in the aforementioned example embodiments, the power delivery structures 250, 250A, 250B, and 250C may be rail structures formed in a trench structure, rather than a via structure formed in a hole structure.

Referring to FIG. 10, only the second conductive barrier portion 252C may be disposed in the contact region CT of the first contact plug 125 and the second contact plug 255 without the first conductive barrier 122, such that contact resistance between the buried conductive structure 120D and the power delivery structure 250D may improve. Also, a region adjacent to the bottom surface 255B among side surfaces of the second contact plug 255 may be exposed. The second conductive barrier 252 may have a portion 252E extending along the side region thereof. By increasing the contact area by the extended portion 252E, contact resistance may significantly improve.

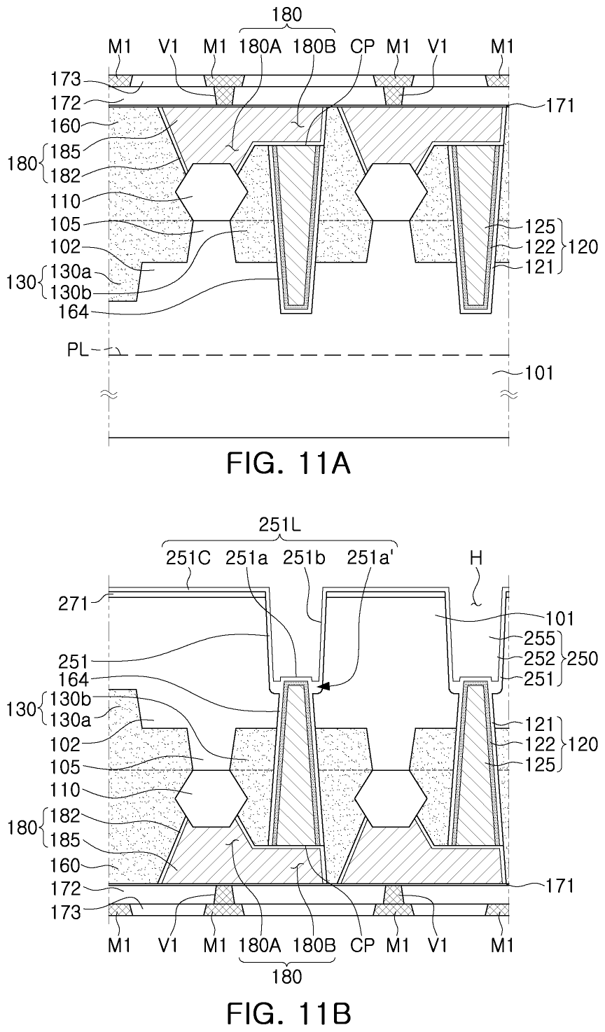

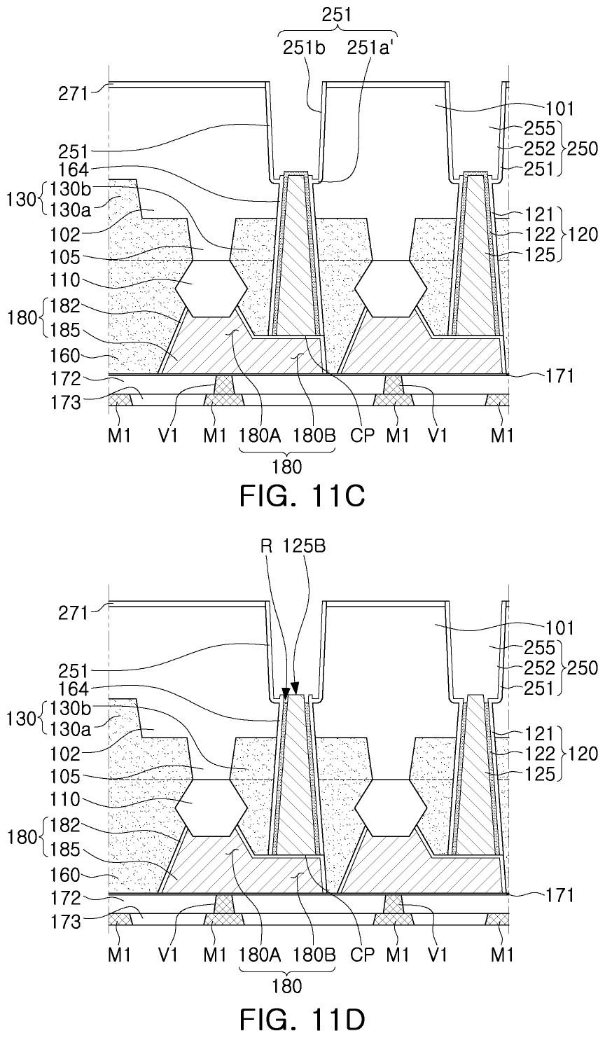

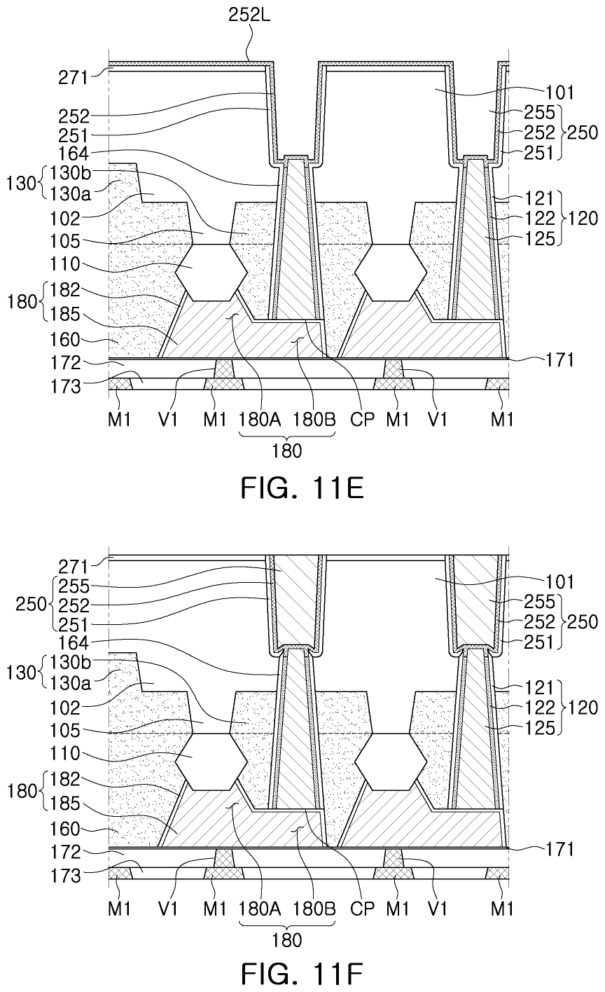

FIGS. 11A to 11F are cross-sectional diagrams illustrating processes of a method of manufacturing the semiconductor device 100 illustrated in FIG. 2.

Referring to FIG. 11A, a gate-all-around type field effect transistor may be formed on the first surface of the substrate. Specifically, such a transistor may include a fin-type active pattern 105, semiconductor patterns SP stacked and spaced apart from each other on the fin-type active pattern 105, a gate structure GS intersecting the fin-type active pattern 105, and a source/drain region 110 disposed on the fin-type active pattern 105 on both sides of the gate structure GS and connected to both sides of the semiconductor patterns SP.

A buried conductive structure 120 penetrating through the isolation insulating layer 130 and a partial region of the substrate 101 may be formed. The buried conductive structure 120 may be formed by forming the first insulating liner 121 and the first conductive barrier 122 in sequence, and filling the remaining space with the first contact plug 125. A contact hole connected to both the source/drain region 110 and the buried conductive structure 120 may be formed in the interlayer insulating layer 160, the conductive barrier 182 and the contact plug 185 may be connected in sequence to fill the contact hole, and a planarization process such as CMP may be performed, such that the upper surface of the contact structure 180 and the upper surface of the interlayer insulating layer 160 may be substantially coplanar with each other. Thereafter, a first wiring portion ML1 connected to the contact structure 180 may be formed on the interlayer insulating layer 160.

Thereafter, to reduce the thickness of the substrate 101, a grinding process may be performed on the second surface of the substrate 101. For example, the grinding process may be performed up to the portion marked “PL.”

Referring to FIG. 11B, a state in which the second surface of the substrate 101 is inverted to face upwardly after performing the grinding process on the structure illustrated in FIG. 11A is illustrated. In this process, a back insulating layer 210 for passivation may be formed on the second surface of the substrate 101, and after the connection hole H is formed in the substrate 101, an insulating liner layer 251L may be formed on the internal surface of the connection hole H.

A connection hole H may be formed to be connected to the buried conductive structure 120 from the second surface of the substrate 101. A partial region of the buried conductive structure 120 may be exposed from a bottom surface (also referred to as an “upper surface” in the description of the aforementioned example embodiment) of the connection hole H. In this process, the exposed region of the buried conductive structure 120 may be an end of the first contact plug 125 in which the first conductive barrier 122 and the first insulating liner 121 are covered in sequence. A recessed region may be formed around the exposed region of the buried conductive structure 120.

Thereafter, the insulating liner layer 251L may be conformally deposited on the internal surface of the connection hole H also on the second surface of the substrate 101. For example, the deposition process may be formed by an atomic layer deposition (ALD), chemical vapor deposition (CVD), or physical vapor deposition (PVD) process. The insulating liner layer 251L may include a portion 251a disposed on the bottom surface of the connection hole H, a portion 251b disposed on the internal sidewall, and a portion 251c disposed on the upper surface of the rear insulating layer 210. In particular, the insulating liner layer 251L may also be formed in a recessed region disposed around the exposed region of the buried conductive structure 120. By adjusting the width of the recessed region during the formation of the connection hole H, the recessed region around the exposed region may be formed to have a relatively narrow space. The liner portion 251a′ filled in such a narrow space around the exposed region may have a relatively large thickness.

Thereafter, referring to FIG. 11C, an insulating liner 251 may be formed on the internal sidewall of the connection hole H by selectively removing the portions 251a and 251c disposed on the bottom surface of the connection hole H and the second surface of the substrate.

This process may be performed by an anisotropic etching process. The liner portion 251a′ around the exposed region of the buried conductive structure 120 may be disposed on the bottom surface of the connection hole H, and may have a relatively thick thickness such that the liner portion 251a′ may remain even after the anisotropic etching is finished. Accordingly, the liner portion disposed on the internal sidewall of the connection hole H and also the liner portion 251a′ around the exposed region of the buried conductive structure 120 may remain together.

The insulating liner 251 may not be present in the region for contact, but may remain in the region surrounding the region such that the insulating liner 251 may assure electrical insulation between the power delivery structure to be formed in a subsequent process and the substrate 101 (or the active region 102).

Thereafter, referring to FIG. 11D, by selectively removing the first conductive barrier 122 disposed on the end of the buried conductive structure 120, the bottom surface 125B of the first contact plug 125 may be exposed.

In the process of removing the first conductive barrier 122 disposed on the bottom surface 125B of the first contact plug 125, the first conductive barrier 122 portion disposed in the side region adjacent to the bottom surface 125B may also be removed. Accordingly, the bottom surface 125B of the first contact plug 125 may be exposed, and a recess exposed by the adjacent side surface region may also be formed around the bottom surface 125B of the first contact plug 125.

Thereafter, referring to FIG. 11E, a second conductive barrier layer 252L for a power delivery structure may be formed.

The second conductive barrier layer 252L may be conformally formed up to the internal sidewall of the connection hole H and also the bottom surface. Since the bottom surface has a recessed non-uniform surface, the second conductive barrier layer 252L may be formed by an ALD process to conformally from the surface. Since the second conductive barrier layer 252L is filled in the recessed region as described above, the bottom surface of the second contact plug 255 and also the adjacent side region may be secured as the contact region.

Thereafter, referring to FIG. 11F, a conductive material may be deposited such that the second contact plug 255 may be filled in the connection hole H, a planarization process such as CMP may be performed to remove the second conductive barrier layer portion disposed on the wiring insulating layer together. Accordingly, the conductive through structure, i.e. power delivery structure 250 extending from the second surface of the substrate 101 and connected to the buried conductive structure 120 may be formed. By forming the second wiring portion ML2 connected to the conductive structure in a subsequent process, the semiconductor device 100 illustrated in FIG. 2 may be manufactured.

Through this process, by removing the first conductive barrier 122, which is a large resistive element, from the contact interfacial surface between the buried conductive structure 120 and the power delivery structure 250, only the second conductive barrier 252 may be disposed. Also, by exposing one region of the side surfaces of the second contact plug 255 adjacent to the bottom surface 255B, the contact region may be increased. Accordingly, contact resistance between the buried conductive structure 120 and the power delivery structure 250 may greatly improve.

According to the aforementioned example embodiments, by removing the first conductive barrier, which is a resistive element, from the contact interfacial surface between the buried conductive structure and the power delivery structure and disposing only the second conductive barrier, contact resistance may improve. Also, by exposing one region of the side surfaces of the second contact plug 255 adjacent to the bottom surface 255B, the contact region may be increased, thereby greatly improving contact resistance.

While the example embodiments have been illustrated and described above, it will be apparent to those skilled in the art that modifications and variations could be made without departing from the scope of the present disclosure as defined by the appended claims.

What is claimed is:

1. A semiconductor device, comprising:
a substrate having first and second surfaces opposing each other, and comprising a fin-type active pattern that extends in a first direction;
an isolation insulating layer on side surfaces of the fin-type active pattern;
a gate structure that extends in a second direction and intersects the fin-type active pattern;
source/drain regions on the fin-type active pattern and on side surfaces of the gate structure;
an interlayer insulating layer on the isolation insulating layer, on side surfaces of the gate structure and on the source/drain region;
a contact structure that penetrates the interlayer insulating layer and is electrically connected to the source/drain regions;
a buried conductive structure electrically connected to the contact structure and in the interlayer insulating layer and the isolation insulating layer; and
a power delivery structure that extends from the second surface of the substrate toward the first surface of the substrate, is in contact with a bottom surface of the buried conductive structure, and is electrically connected to the buried conductive structure,
wherein the buried conductive structure comprises a first contact plug, a first conductive barrier on a side surface of the first contact plug and spaced apart from a bottom portion of the side surface of the first contact plug, and a first insulating liner on the first conductive barrier, and
wherein the power delivery structure comprises a second contact plug, a second conductive barrier on a side surface of the second contact plug and an upper surface of the second contact plug and in direct contact with a bottom surface of the first contact plug, and a second insulating liner between the second conductive barrier and the substrate.

2. The semiconductor device of claim 1, wherein the first conductive barrier is open in a side region that is adjacent to the bottom surface of the first contact plug.

3. The semiconductor device of claim 2, wherein the second conductive barrier has an extended portion that extends along a portion of the side region of the first contact plug.

4. The semiconductor device of claim 3, wherein the extended portion of the second conductive barrier is between the side surface of the first contact plug and the first insulating liner.

5. The semiconductor device of claim 1,
wherein the second conductive barrier has a first region in contact with the bottom surface of the first contact plug and a second region on side surfaces of the second contact plug, and
wherein the first region is recessed toward the bottom surface of the first contact plug.

6. The semiconductor device of claim 1, wherein the first conductive barrier and the second conductive barrier comprise different conductive materials.

7. The semiconductor device of claim 1, wherein the buried conductive structure extends into the substrate through the isolation insulating layer, and the buried conductive structure is in contact with the power delivery structure in the substrate.

8. The semiconductor device of claim 7,
wherein an upper surface of the power delivery structure has a first region in contact with the bottom surface of the buried conductive structure, and a second region on a side surface of the buried conductive structure, and
wherein the second insulating liner has a portion that extends onto an upper surface of the second conductive barrier.

9. The semiconductor device of claim 1,
wherein the buried conductive structure extends to the first surface of the substrate through the isolation insulating layer, and
wherein the buried conductive structure is in contact with the power delivery structure in a region adjacent to the first surface of the substrate of the isolation insulating layer.

10. The semiconductor device of claim 9,
wherein an upper surface of the power delivery structure has a first region in contact with the bottom surface of the buried conductive structure, and a second region that is in contact with the isolation insulating layer.

11. The semiconductor device of claim 1, further comprising:
a plurality of channel layers spaced apart from each other in a direction perpendicular to the first surface of the substrate on the fin-type active pattern,
wherein the gate structure comprises a gate electrode on the plurality of channel layers and extending in the second direction, and a gate insulating layer between the plurality of channel layers and the gate electrode.

12. The semiconductor device of claim 1, wherein the power delivery structure comprises a through-via structure.

13. The semiconductor device of claim 1, wherein the power delivery structure comprises a rail structure that extends in the first direction.

14. A semiconductor device, comprising:
a substrate having first and second surfaces opposing each other, that extends in a first direction, and comprising a fin-type active pattern defined by an isolation insulating layer;
a source/drain region on the fin-type active pattern;
an interlayer insulating layer on the isolation insulating layer and on the source/drain regions;
a contact structure that penetrates the interlayer insulating layer and is electrically connected to the source/drain regions;
a first wiring portion on the interlayer insulating layer and electrically connected to the contact structure;
a buried conductive structure in the interlayer insulating layer and the isolation insulating layer, electrically connected to the contact structure, and having a bottom surface that penetrates the substrate and spaced apart from the second surface of the substrate; and
a second wiring portion on the second surface of the substrate and having a power delivery structure electrically connected to the bottom surface of the buried conductive structure,
wherein the buried conductive structure comprises a first contact plug, a first conductive barrier on a side surface of the first contact plug, and a first insulating liner on the first conductive barrier, and
wherein the power delivery structure comprises a second contact plug, and a second conductive barrier on a side surface and an upper surface of the second contact plug and in direct contact with a bottom surface of the first contact plug.

15. The semiconductor device of claim 14,
wherein the first conductive barrier is open in a side region that is adjacent to the bottom surface of the first contact plug, and
wherein the second conductive barrier has a portion that extends along the side region of the first contact plug.

16. The semiconductor device of claim 14, wherein a width of the bottom surface of the buried conductive structure is in a range of 0.3 to 1.2 times a width of an upper surface of the power delivery structure.

17. The semiconductor device of claim 14,
wherein the second conductive barrier has a first region in contact with the bottom surface of the first contact plug and a second region on side surfaces of the second contact plug, and
wherein the first region is recessed toward the bottom surface of the first contact plug.

18. The semiconductor device of claim 14, wherein at least one of the first conductive barrier and the second conductive barrier comprises a material selected from a group consisting of Ta, TaN, Mn, MnN, WN, Ti, and TiN.

19. The semiconductor device of claim 14,
wherein the power delivery structure further comprises a second insulating liner that is between the second conductive barrier and the substrate, and
wherein at least one of the first insulating liner and the second insulating liner comprises a material selected from a group consisting of SiO2, SiN, SiCN, SiC, SiCOH, SiON, Al2O3, and AlN.

20. A semiconductor device, comprising:
a substrate having a first surface and a second surface opposing each other, and comprising an active region defined by a first isolation insulating layer;
a fin-type active pattern that extends in a first direction on the active region and is defined by a second isolation insulating layer having a depth less than a depth of the first isolation insulating layer with respect to the substrate;
a source/drain region on the fin-type active pattern;
a plurality of channel layers that are stacked and spaced apart from each other on the fin-type active pattern;
a gate electrode that extends across the fin-type active pattern in a second direction that intersects the first direction, and is on the plurality of channel layers;
a gate insulating layer between the plurality of channel layers and the gate electrode;
an interlayer insulating layer on the second isolation insulating layer and on the gate electrode and the source/drain regions;
a contact structure that penetrates the interlayer insulating layer and is electrically connected to the source/drain regions;
a buried conductive structure electrically connected to the contact structure, this is in the first isolation insulating layer and the second isolation insulating layer, and extends into the substrate; and
a power delivery structure that extends into the substrate from the second surface of the substrate and is electrically connected to a bottom surface of the buried conductive structure,
wherein the buried conductive structure comprises a first contact plug, a first conductive barrier on a side surface of the first contact plug, and a first insulating liner on the first conductive barrier, and
wherein the power delivery structure comprises a second contact plug, a second conductive barrier on a side surface and an upper surface of the second contact plug and in direct contact with a bottom surface of the first contact plug, and a second insulating liner between the second conductive barrier and the substrate.
